(19) United States
(12) Patent Application Publication
(10) Pub. No.: US 2020/0395391 A1
(43) Pub. Date: Dec. 17, 2020

(54) AN ARRAY SUBSTRATE, A DISPLAY PANEL AND A METHOD FOR MANUFACTURING THE ARRAY SUBSTRATE

(71) Applicant: Wuhan China Star Optoelectronics Technology Co., Ltd., Wuhan, Hubei (CN)

(72) Inventor: Wentao DING, Wuhan, Hubei (CN)

(21) Appl. No.: 16/612,419

(22) PCT Filed: Sep. 10, 2019
(86) PCT No.: PCT/CN2019/105085

§ 371 Date: Nov. 11, 2019

(30) Foreign Application Priority Data
Jun. 12, 2019 (CN) 201910507308.8

(51) Int. Cl. H01L 27/12; H01L 23/544

(52) U.S. Cl. CPC H01L 27/1262; H01L 2223/54426; H01L 27/1218; H01L 23/544

(57) ABSTRACT

The present invention provides an array substrate, a display panel and a method for manufacturing the array substrate. The array substrate includes a substrate layer, a buffer layer, a mark layer and a thin film transistor layer, which are stacked. The buffer layer is disposed on the substrate layer and includes at least two stacked inorganic layers, stresses of which are mutually offset. The mark layer is disposed on one side of the buffer layer away from the substrate layer. The thin film transistor layer is disposed on the side of the buffer layer with the mark layer. The display panel includes the array substrate. The method for manufacturing the array substrate includes: providing a substrate, fabricating a substrate layer, fabricating a buffer layer and fabricating a thin film transistor layer.

### BACKGROUND OF THE INVENTION

### 1. Field of the Invention

The present invention relates to a display technical field, and more particularly to an array substrate, a display panel and a method for manufacturing the array substrate.

### 2. Description of the Prior Art

With the advancement of science and technology and the development of the times, people's demand for a display screen of a mobile phone is also getting higher and higher. At present, the mainstream rigid display screen can not meet the market demand, so the development of the flexible display screen is particularly important. Compared with the rigid display screen process, an array substrate of a flexible TFT-LCD (Thin Film Transistor Liquid Crystal Display) employs a polyimide (PI) substrate layer in the process. And a buffer layer on the substrate layer is a single SiNx layer or a single SiO₂ layer. Edges of the single SiNx layer will rise away from the substrate layer and produce tension, and edges of the single SiO2 layer will bend toward the substrate layer and produce pressure. Thus, when only the single SiNx layer or the single SiO2 layer is used to make the buffer layer, the film stress will lead to separation of the single SiNx layer or the single SiO2 layer and the films above or below it, and further lead to the failure of the array substrate. Because the buffer layer is easily separated from the substrate layer in the process of the array substrate, alignment marks on the buffer layer will be lost with the separation of the buffer layer from the substrate layer, resulting in the termination of subsequent exposure process due to the absence of the identifiable alignment marks.

Hence, it is necessary to provide a new array substrate, a display panel and a method for manufacturing the array substrate to overcome the problems existing in the prior art.

### BRIEF SUMMARY OF THE INVENTION

### Technical Problem

One object of the present invention is to provide an array substrate, a display panel and a method for manufacturing the array substrate, which can increase the adhesion force between a buffer layer and a substrate layer by improving the structure of the buffer layer, thereby retaining alignment marks, and solving the problems that the buffer layer is easily separated from the substrate layer due to the insufficient adhesion force between the buffer layer and the substrate layer and the alignment marks are lost in the manufacturing process of the array substrate.

### Technical Solutions

To solve the above technical problems, one embodiment of the present invention provides an array substrate, comprising: a substrate layer, a buffer layer, a mark layer and a thin film transistor layer, which are stacked. Specifically, the buffer layer is disposed on the substrate layer and includes at least two stacked inorganic layers, stresses of which are mutually offset. The mark layer is disposed on one side of the buffer layer away from the substrate layer. The thin film transistor layer is disposed on the side of the buffer layer with the mark layer.

Further, in the buffer layer, the number of the inorganic layers is odd.

Further, the buffer layer has three inorganic layers, including: a first inorganic layer, being disposed on the substrate layer, and being made of silicon nitride; a second inorganic layer, being disposed on one side of the first inorganic layer away from the substrate layer, and being made of silicon oxide; and a third inorganic layer, being disposed on one side of the second inorganic layer away from the first inorganic layer, and is made of silicon nitride.

Further, the buffer layer has five inorganic layers, including: a first inorganic layer, being disposed on the substrate layer, and being made of silicon nitride; a second inorganic layer, being disposed on one side of the first inorganic layer away from the substrate layer, and being made of silicon oxide; a third inorganic layer, being disposed on one side of the second inorganic layer away from the first inorganic layer, and being made of silicon nitride; a fourth inorganic layer, being disposed on one side of the third inorganic layer away from the substrate layer, and being made of silicon oxide; and a fifth inorganic layer, being disposed on one side of the fourth inorganic layer away from the third inorganic layer, and being made of silicon nitride.

Further, the first inorganic layer, the second inorganic layer, the third inorganic layer, the fourth inorganic layer and the fifth inorganic layer have the same thickness.

Further, the mark layer includes a plurality of alignment marks, which are arranged along a periphery of the mark layer.

The other embodiment of the present invention provides a method for manufacturing an array substrate, comprising the follow steps:

fabricating a substrate layer;

fabricating at least two stacked inorganic layers, stresses of which are mutually offset on the substrate layer to form a buffer layer;

fabricating a mark layer on one side of the buffer layer away from the substrate layer; and

fabricating a thin film transistor layer on the side of the buffer layer with the mark layer.

Further, the step of fabricating the buffer layer includes the following steps:

depositing a silicon nitride material on the substrate layer to form a first inorganic layer;

depositing a silicon oxide material on the first inorganic layer to form a second inorganic layer; and

depositing a silicon nitride material on the second inorganic layer to form a third inorganic layer.

Further, the step of fabricating the buffer layer includes the following steps:

depositing a silicon nitride material on the substrate layer to form a first inorganic layer;

depositing a silicon oxide material on the first inorganic layer to form a second inorganic layer;

depositing a silicon nitride material on the second inorganic layer to form a third inorganic layer;

depositing a silicon oxide material on the third inorganic layer to form a fourth inorganic layer; and

depositing a silicon nitride material on the fourth inorganic layer to form a fifth inorganic layer.

Another embodiment of the present invention provides a display panel, including the array substrate described above.

### Beneficial Effect

The beneficial effect of the present invention is that: the present invention provides an array substrate, a display panel and a method for manufacturing the array substrate, to increase the adhesion force between the buffer layer and the substrate layer by improving the structure of the buffer layer, thereby retaining the alignment marks, and solving the problems that the buffer layer is easily separated from the substrate layer due to the insufficient adhesion force between the buffer layer and the substrate layer and the alignment marks are lost in the manufacturing process of the array substrate.

### BRIEF DESCRIPTION OF THE DRAWINGS

FIG. 1 is a structure schematic view of an array substrate of a first embodiment of the present invention;

FIG. 2 is a top view of a buffer layer of the first embodiment of the present invention, which mainly shows the distribution of alignment marks;

FIG. 3 is a structure schematic view of a thin film transistor layer of the first embodiment of the present invention;

FIG. 4 is a structure schematic view of the array substrate of a second embodiment of the present invention;

FIG. 5 is a flow chart of a method for manufacturing the array substrate in one embodiment of the present invention;

FIG. 6 is a flow chart for manufacturing the buffer layer in the first embodiment of the present invention; and

FIG. 7 is a flow chart for manufacturing the buffer layer in the second embodiment of the present invention.

Reference numerals in the above drawings:
1 substrate layer
2 buffer layer
3 mark layer
4 thin film transistor layer
5 cathode layer
6 protection layer
10 alignment mark
20 glass substrate
21a, 21b first inorganic layer
22a, 22b second inorganic layer
23a, 23b third inorganic layer
24 fourth inorganic layer
25 fifth inorganic layer
41 gate layer
42 gate insulating layer
43 active layer
44 source-drain layer
100 array substrate

### DETAILED DESCRIPTION OF THE PREFERRED EMBODIMENTS

The following text will clearly and completely describe preferred embodiments of the present invention with reference to the accompanying drawings, in order to fully introduce the technical contents of the present invention to technicians in the field, and to demonstrate with examples that the present invention can be implemented, so as to make the technical contents of the present invention clearer and make it easier for technicians in the field to understand how to implement the present invention. However, the present invention can be embodied by many different forms of embodiments. The protection scope of the present invention is not limited to the embodiments mentioned herein, and the description of the embodiments below is not intended to limit the scope of the present invention.

The directional terms mentioned in the present invention, such as “up”, “down”, “front”, “rear”, “left”, “right”, “inside”, “outside”, “side”, etc., are only used to represent the directions in the drawings. The directional terms used in this paper are used to explain the present invention, rather than to limit the protection scope of the present invention.

In the accompanying drawings, components with the same structure are represented by the same reference numerals, and components with similar structures or functions are represented by similar reference numerals. In addition, for ease of understanding and description, the size and thickness of each component shown in the drawings are arbitrarily shown, and the present invention does not limit the size and thickness of each component.

When one component is described as “on” another component, the component may be directly disposed on another component, also may be disposed on the another component through one intermediate component. When one component is described as “installed on” or “connected to” another component, the both can be understood as direct “installation” or “connection”, or “installation” or “connection” through one intermediate component.

### Embodiment 1

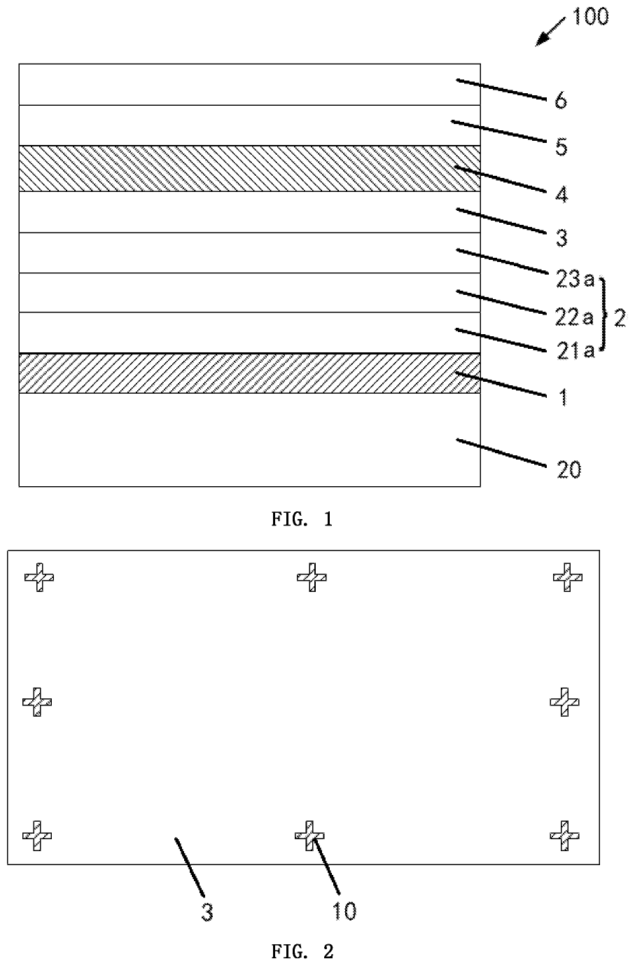

Please refer to FIG. 1, in a first embodiment, the present invention provides an array substrate 100, including a substrate layer 1, a buffer layer 2, a mark layer 3 and a thin film transistor layer 4, which are stacked. Specifically, the buffer layer 2 is disposed on the substrate layer 1. The buffer layer 2 includes at least two inorganic layers, which are stacked, and stresses of which are mutually offset. The mark layer 3 is disposed on one side of the buffer layer 2 away from the substrate layer 1. The thin film transistor layer 4 is disposed on the side of the buffer layer 2 with the mark layer 3. The substrate layer 1 is made of polyimide (PI) or other buffer materials to provide buffer protection.

In order to mutually offset stresses, the number of the inorganic layers of the buffer layer 2 is odd. In the embodiment, the buffer layer 2 has three inorganic layers, including a first inorganic layer 21a, a second inorganic layer 22a and a third inorganic layer 23a. Specifically, the first inorganic layer 21a is disposed on the substrate layer 1, and is made of silicon nitride. The second inorganic layer 22a is disposed on one side of the first inorganic layer 21a away from the substrate layer 2, and is made of silicon oxide. The third inorganic layer 23a is disposed on one side of the second inorganic layer 22a away from the first inorganic layer 21a, and is made of silicon nitride. In the embodiment, the first inorganic layer 21a made of silicon nitride can be tightly combined with the substrate layer 2. Because the combination force between silicon nitride and polyimide is greater than that between silicon oxide and polyimide, the adhesive force between the buffer layer 2 and the substrate layer 1 is increased. If a single SiNx film (e.g., the first inorganic layer 21a) is attached to the substrate layer 1, edges of the single SiNx film will rise away from the substrate layer 1 and produce tension. If a single SiO2 film (e.g., the second inorganic layer 22a) is attached to the substrate layer 1, and edges of the single SiO2 film will bend toward the substrate layer 1 and produce pressure. By overlapping the SiNx film and SiO2 film, the tension produced by the SiNx film and the pressure produced by the SiO2 film can be offset each other. Namely, the stresses of the first inorganic layer 21a and the second inorganic layer 22a are offset each other, and the stresses of the second inorganic layer 22a and the third inorganic layer 23a are also offset each other, thereby reducing the stresses produced in the buffer layer 2 and avoiding separation of the buffer layer 2 from the substrate layer 1. Compared with the existing buffer layer with a single SiNx layer or a single SiO2 layer, the buffer layer 2 of the present invention skillfully utilizes the opposite stresses of the SiNx film and the SiO2 film to offset each other, for effectively avoiding the influence of the stresses.

In the embodiment, the first inorganic layer 21a, the second inorganic layer 22a and the third inorganic layer 23a have the same thickness, for making the tension and the pressure efficiently offset, reducing the stresses produced in the buffer layer 2 and avoiding separation of the buffer layer 2 from the substrate layer 1.

Optionally, the second inorganic layer 22a and the third inorganic layer 23a may be repeatedly attached for many times to form a film stacking structure interlaced with the silicon nitride films and the silicon oxide films. Namely, the formed buffer layer 2 can be the film stacking structure with odd layers, such as three layers, five layers or seven layers.

Please refer to FIG. 2, in the embodiment, the mark layer 3 includes a plurality of alignment marks 10, which are arranged along a periphery of the mark layer 3. Specifically, the alignment marks 10 may be distributed at four corners of the mark layer 3 or at edges of the mark layer 3, so that the requirement of setting the alignment marks 10 can be met without affecting other functions. Generally, the alignment mark 10 is cross-shaped to facilitate alignment. Since the buffer layer 2 and the substrate layer 1 will not be separated, the alignment marks 10 will be preserved completely, thus facilitating to identify and align according to the alignment marks 10 in the subsequent exposure process.

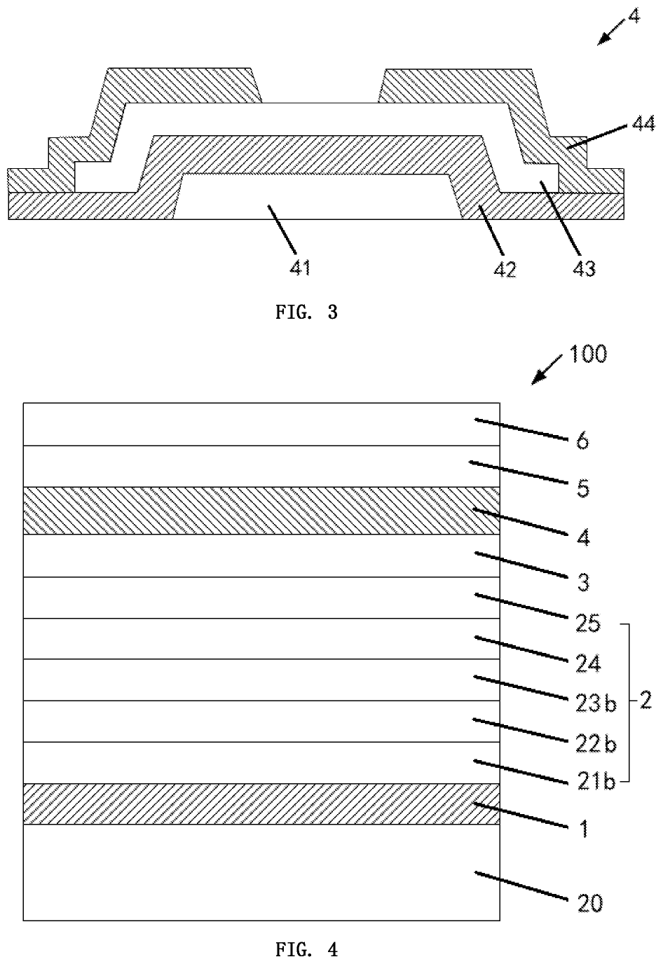

Please refer to FIG. 3, in the embodiment, the thin film transistor layer 4 includes a gate layer 41, a gate insulating layer 42, an active layer 43 and a source-drain layer 44. Specifically, the gate layer 41 is disposed on one side of the buffer layer 2 away from the substrate layer 1. The gate insulating layer 42 is disposed on one side of the gate layer 41 away from the buffer layer 2. The active layer 43 is disposed on one side of the gate insulating layer 42 away from the gate layer 41. The source-drain layer 44 is disposed on one side of the active layer 43 away from the gate insulating layer 42. It should be noted that the structure of the thin film transistor layer 4 shown in FIG. 3 is only an illustration, not a limitation of the protection scope of the present invention. All the structures of the thin film transistor layer 4 in the prior art belong to the protection scope of the present invention.

Please refer to FIG. 1, in the embodiment, the array substrate 100 further includes a cathode layer 5 and a protection layer 6. Specifically, the cathode layer 5 is disposed on the thin film transistor layer 4 away from the buffer layer 2. The protection layer 6 is completely coated on the cathode layer 5 away from the thin film transistor layer 4. The protection layer 6 can completely cover an upper surface of the cathode layer 5 to protect the thin film transistor layer 4, reduce the possibility of water and oxygen intrusion, and improve the performance of display panel.

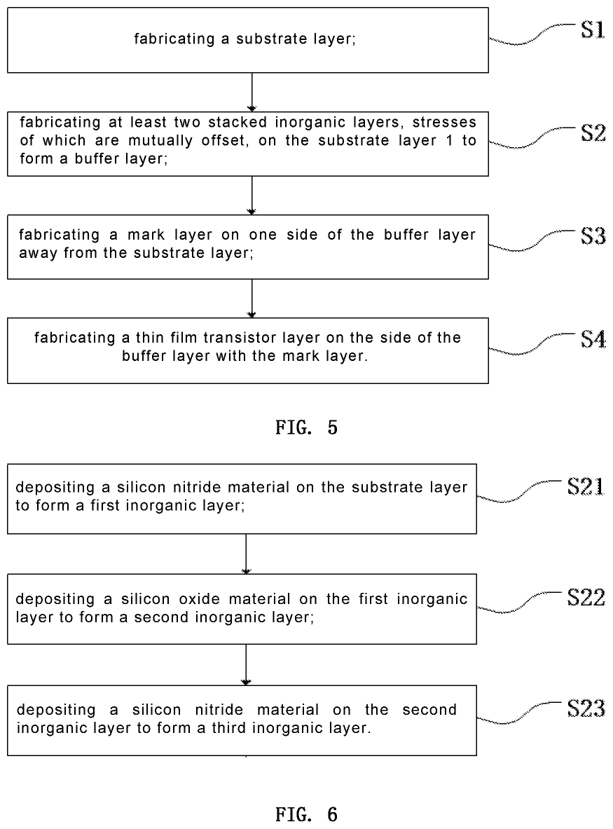

Please refer to FIG. 5, in one embodiment, the present invention provides a method for manufacturing the array substrate 100. The method includes the follow steps S1-S4.

A step S1 is fabricating a substrate layer 1. The material of the substrate layer 1 is polyimide (PI) or other buffer materials, which plays the role of buffer protection.

A step S2 is fabricating at least two stacked inorganic layers, stresses of which are mutually offset, on the substrate layer 1 to form a buffer layer 2. In this way, on the one hand, the stresses generated in the buffer layer 2 can be effectively eliminated, and the tension and pressure can be offset each other.

A step S3 is fabricating a mark layer 3 on one side of the buffer layer 2 away from the substrate layer 1.

A step S4 is fabricating a thin film transistor layer 4 on the side of the buffer layer 2 with the mark layer 3.

Please refer to FIG. 6, in the embodiment, the step of fabricating the buffer layer 2 includes the following steps S21-S23.

A step S21 is depositing a silicon nitride material on the substrate layer 1 to form a first inorganic layer 21a. The silicon nitride material is used as the first inorganic layer 21a to make the silicon nitride material bond closely with the substrate layer 1. The bonding force between silicon nitride and polyimide is greater than that between silicon oxide and polyimide, thereby increasing the bonding force between the buffer layer 2 and the substrate layer 1.

A step S22 is depositing a silicon oxide material on the first inorganic layer 21a to form a second inorganic layer 22a.

A step S23 is depositing a silicon nitride material on the second inorganic layer 22a to form a third inorganic layer 23a.

It is worth noting that, if a single SiNx film (e.g., the first inorganic layer 21a) is attached to the substrate layer 1, edges of the single SiNx film will rise away from the substrate layer 1 and produce tension. If a single SiO2 film (e.g., the second inorganic layer 22a) is attached to the substrate layer 1, and edges of the single SiO2 film will bend toward the substrate layer 1 and produce pressure. By overlapping the SiNx film and SiO2 film, the tension produced by the SiNx film and the pressure produced by the SiO2 film can be offset each other. Namely, the stresses of the first inorganic layer 21a and the second inorganic layer 22a are offset each other, and the stresses of the second inorganic layer 22a and the third inorganic layer 23a are also offset each other, thereby reducing the stresses produced in the buffer layer 2 and avoiding separation of the buffer layer 2 from the substrate layer 1. Compared with the existing buffer layer with a single SiNx layer or a single SiO2 layer, the buffer layer 2 of the present invention skillfully utilizes the opposite stresses of the SiNx film and the SiO2 film to offset each other, for effectively avoiding the influence of the stresses.

### Embodiment 2

Please refer to FIG. 4, a second embodiment of the present invention includes all the technical features of the first embodiment. The difference between them is that, the number of the inorganic layers of the buffer layer 2 is five in the second embodiment. Specifically, the buffer layer 2 includes a first inorganic layer 21b, a second inorganic layer 22b, a third inorganic layer 23b, a fourth inorganic layer 24 and a fifth inorganic layer 25. Wherein the first inorganic layer 21b is disposed on the substrate layer 1, and is made of silicon nitride. The second inorganic layer 22b is disposed on one side of the first inorganic layer 21b away from the substrate layer 2, and is made of silicon oxide. The third inorganic layer 23b is disposed on one side of the second inorganic layer 22b away from the first inorganic layer 21b, and is made of silicon nitride. The fourth inorganic layer 24 is disposed on one side of the third inorganic layer 23b away from the substrate layer, and is made of silicon oxide. The fifth inorganic layer 25 is disposed on one side of the fourth inorganic layer 24 away from the third inorganic layer 23b, and is made of silicon nitride. The silicon nitride material is used as the first inorganic layer 21b to make the silicon nitride material bond closely with the substrate layer 1. The bonding force between silicon nitride and polyimide is greater than that between silicon oxide and polyimide, thereby increasing the bonding force between the buffer layer 2 and the substrate layer 1. Similarly, the stresses of the fourth inorganic layer 24 and the fifth inorganic layer 25 are offset each other, thereby reducing the stresses produced in the buffer layer 2 and avoiding separation of the buffer layer 2 from the substrate layer 1.

Please refer to FIG. 4, in the embodiment, the buffer layer 2 is preferably set to five layers. On the one hand, the stresses generated in the buffer layer 2 can be effectively eliminated, and the tension and pressure can be offset each other. On the other hand, the buffer layer 2 of the present invention can reduce the manufacturing cost and ensure the lightening and thinning of the array substrate 100.

In the embodiment, the first inorganic layer 21a, the second inorganic layer 22a and the third inorganic layer 23a have the same thickness, for making the tension and the pressure efficiently offset, reducing the stresses produced in the buffer layer 2 and avoiding separation of the buffer layer 2 from the substrate layer 1.

Please refer to FIG. 5, in one embodiment, the present invention provides a method for manufacturing the array substrate 100. The method includes the follow steps S1-S4.

A step S1 is fabricating a substrate layer 1. The material of the substrate layer 1 is polyimide (PI) or other buffer materials, which plays the role of buffer protection.

A step S2 is fabricating at least two stacked inorganic layers, stresses of which are mutually offset, on the substrate layer 1 to form a buffer layer 2. In this way, on the one hand, the stresses generated in the buffer layer 2 can be effectively eliminated, and the tension and pressure can be offset each other.

A step S3 is fabricating a mark layer 3 on one side of the buffer layer 2 away from the substrate layer 1.

A step S4 is fabricating a thin film transistor layer 4 on the side of the buffer layer 2 with the mark layer 3.

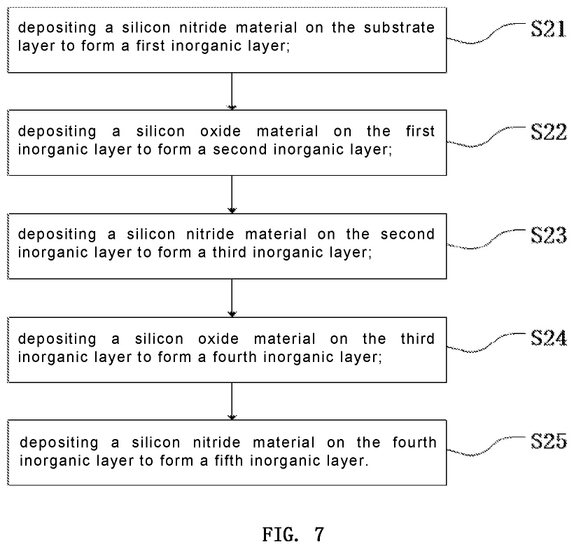

Please refer to FIG. 7, in the embodiment, the step of fabricating the buffer layer 2 includes the following steps S21-S25.

A step S21 is depositing a silicon nitride material on the substrate layer 1 to form a first inorganic layer 21b. The silicon nitride material is used as the first inorganic layer 21b to make the silicon nitride material bond closely with the substrate layer 1. The bonding force between silicon nitride and polyimide is greater than that between silicon oxide and polyimide, thereby increasing the bonding force between the buffer layer 2 and the substrate layer 1.

A step S22 is depositing a silicon oxide material on the first inorganic layer 21b to form a second inorganic layer 22b.

A step S23 is depositing a silicon nitride material on the second inorganic layer 22b to form a third inorganic layer 23b.

A step S24 is depositing a silicon oxide material on the third inorganic layer 23b to form a fourth inorganic layer 24.

A step S25 is depositing a silicon nitride material on the fourth inorganic layer 24 to form a fifth inorganic layer 25.

It is worth noting that, if a single SiNx film (e.g., the first inorganic layer 21b) is attached to the substrate layer 1, edges of the single SiNx film will rise away from the substrate layer 1 and produce tension. If a single SiO2 film (e.g., the second inorganic layer 22b) is attached to the substrate layer 1, and edges of the single SiO2 film will bend toward the substrate layer 1 and produce pressure. By overlapping the SiNx film and SiO2 film, the tension produced by the SiNx film and the pressure produced by the SiO2 film can be offset each other. Namely, the stresses of the first inorganic layer 21b and the second inorganic layer 22b are offset each other, the stresses of the second inorganic layer 22b and the third inorganic layer 23b are offset each other, and the stresses of the fourth inorganic layer 24 and the fifth inorganic layer 25 are also offset each other, thereby reducing the stresses produced in the buffer layer 2 and avoiding separation of the buffer layer 2 from the substrate layer 1. Compared with the existing buffer layer with a single SiNx layer or a single SiO2 layer, the buffer layer 2 of the present invention skillfully utilizes the opposite stresses of the SiNx film and the SiO2 film to offset each other, for effectively avoiding the influence of the stresses.

In the embodiment, the buffer layer 2 is preferably set to five layers. On the one hand, the stresses generated in the buffer layer 2 can be effectively eliminated, and the tension and pressure can be offset each other. On the other hand, the buffer layer 2 of the present invention can reduce the manufacturing cost and ensure the lightening and thinning of the array substrate 100.

In the embodiment, the film thickness of the deposited silicon nitride material is the same as that of the deposited silicon oxide material. Both are fabricated by at least one of the methods of vapor deposition, atomic deposition, pulsed laser deposition or sputtering. The first inorganic layer 21b, the second inorganic layer 22b, the third inorganic layer 23b, the fourth inorganic layer 24 and the fifth inorganic layer 25 have the same thickness, for making the tension and the pressure efficiently offset, reducing the stresses produced in the buffer layer 2 and avoiding separation of the buffer layer 2 from the substrate layer 1.

Based on the same inventive concept, one embodiment of the present invention provides a display panel, which includes the array substrate 100 described in Embodiments 1 or 2. The main contents of the invention are as follows: the buffer layer 2 of the array substrate 100 includes at least two inorganic layers, which are stacked, and stresses of which are mutually offset. The two inorganic layers are made of SiNx and SiO2 respectively. By overlapping the SiNx film and SiO2 film, the tension produced by the SiNx film and the pressure produced by the SiO2 film can be offset each other, thereby reducing the stresses produced in the buffer layer 2 and avoiding separation of the buffer layer 2 from the substrate layer 1. Compared with the existing buffer layer with a single SiNx layer or a single SiO2 layer, the buffer layer 2 of the present invention skillfully utilizes the opposite stresses of the SiNx film and the SiO2 film to offset each other, for effectively avoiding the influence of the stresses. The present invention can increase the adhesion force between the buffer layer 2 and the substrate layer 1 by improving the structure of the buffer layer, thereby retaining the alignment marks 10, and solving the problems that the alignment marks 10 are lost due to the fall-off of the buffer layer 2.

Wherein, the buffer layer 2 can be arranged as an odd-layer film stacking structure, preferably five layers. On the one hand, the stresses generated in the buffer layer 2 can be effectively eliminated, and the tension and pressure can be offset each other. On the other hand, the buffer layer of the present invention can reduce the manufacturing cost and ensure the lightening and thinning of the array substrate 100.

The display panel of the present invention may be any product or component with display function such as wearable device, mobile phone, tablet computer, TV, display, notebook computer, electronic book, electronic newspaper, digital photo frame, navigator, etc. Wherein, the wearable device includes smart bracelet, smart watch, VR (Virtual Reality) and other devices.

The beneficial effect of the present invention is that: the present invention provides the array substrate, the display panel and the method for manufacturing the array substrate, to increase the adhesion force between the buffer layer and the substrate layer by improving the structure of the buffer layer, thereby retaining the alignment marks, and solving the problems that the buffer layer is easily separated from the substrate layer due to the insufficient adhesion force between the buffer layer and the substrate layer and the alignment marks are lost in the manufacturing process of the array substrate. The buffer layer of the present invention skillfully utilizes the opposite stresses of the SiNx film and the SiO2 film to offset each other, for effectively avoiding the influence of the stresses.

The above is only the preferred embodiment of the present invention. It should be pointed out that for ordinary technicians in the technical field, without departing from the principles of the present invention, a number of improvements and finishing can also be made, and these improvements and finishing should also be considered as the scope of protection of the present invention.

What is claimed is:

1. An array substrate, comprising:
a substrate layer;
a buffer layer, being disposed on the substrate layer and including at least two stacked inorganic layers, stresses of which are mutually offset;
a mark layer, being disposed on one side of the buffer layer away from the substrate layer; and
a thin film transistor layer, being disposed on the side of the buffer layer with the mark layer.

2. The array substrate as claimed in claim 1, wherein in the buffer layer, the number of the inorganic layers is odd.

3. The array substrate as claimed in claim 1, wherein the buffer layer has three inorganic layers, including:
a first inorganic layer, being disposed on the substrate layer, and being made of silicon nitride;
a second inorganic layer, being disposed on one side of the first inorganic layer away from the substrate layer, and being made of silicon oxide; and
a third inorganic layer, being disposed on one side of the second inorganic layer away from the first inorganic layer, and is made of silicon nitride.

4. The array substrate as claimed in claim 1, wherein the buffer layer has five inorganic layers, including:
a first inorganic layer, being disposed on the substrate layer, and being made of silicon nitride;
a second inorganic layer, being disposed on one side of the first inorganic layer away from the substrate layer, and being made of silicon oxide;
a third inorganic layer, being disposed on one side of the second inorganic layer away from the first inorganic layer, and being made of silicon nitride;
a fourth inorganic layer, being disposed on one side of the third inorganic layer away from the substrate layer, and being made of silicon oxide; and
a fifth inorganic layer, being disposed on one side of the fourth inorganic layer away from the third inorganic layer, and being made of silicon nitride.

5. The array substrate as claimed in claim 1, wherein the mark layer includes a plurality of alignment marks, which are arranged along a periphery of the mark layer.

6. The array substrate as claimed in claim 4, wherein the first inorganic layer, the second inorganic layer, the third inorganic layer, the fourth inorganic layer and the fifth inorganic layer have the same thickness.

7. A method for manufacturing an array substrate, comprising the follow steps:
fabricating a substrate layer;
fabricating at least two stacked inorganic layers, stresses of which are mutually offset on the substrate layer to form a buffer layer;
fabricating a mark layer on one side of the buffer layer away from the substrate layer; and
fabricating a thin film transistor layer on the side of the buffer layer with the mark layer.

8. The method for manufacturing the array substrate as claimed in claim 7, wherein the step of fabricating the buffer layer includes the following steps:
depositing a silicon nitride material on the substrate layer to form a first inorganic layer;
depositing a silicon oxide material on the first inorganic layer to form a second inorganic layer; and
depositing a silicon nitride material on the second inorganic layer to form a third inorganic layer.

9. The method for manufacturing the array substrate as claimed in claim 7, wherein the step of fabricating the buffer layer includes the following steps:
depositing a silicon nitride material on the substrate layer to form a first inorganic layer;
depositing a silicon oxide material on the first inorganic layer to form a second inorganic layer;
depositing a silicon nitride material on the second inorganic layer to form a third inorganic layer;
depositing a silicon oxide material on the third inorganic layer to form a fourth inorganic layer; and
depositing a silicon nitride material on the fourth inorganic layer to form a fifth inorganic layer.

10. A display panel, comprising the array substrate as claimed in claim 1.
